(19) United States
(12) Patent Application Publication
(10) Pub. No.: US 2018/0374413 A1
(43) Pub. Date: Dec. 27, 2018

(54) DISPLAY SYSTEM DRIVER

(71) Applicant: Microsoft Technology Licensing, LLC, Redmond, WA (US)

(72) Inventors: Richard MCCAULEY, Sunnyvale, CA (US); Barry THOMPSON, Menlo Park, CA (US); Stefan M. WURSTER, Livermore, CA (US)

(21) Appl. No.: 15/869,557

(22) Filed: Jan. 12, 2018

Related U.S. Application Data
(60) Provisional application No. 62/523,082, filed on Jun. 21, 2017.

(51) Int. Cl. G09G 3/32; G09G 3/20; H03M 1/66; H01S 5/042

(52) U.S. Cl. CPC G09G 3/32; G09G 3/2003; H03M 1/66; H01S 5/4025; G09G 2310/0291; G09G 2310/08; G09G 2320/0626; H01S 5/0428

(57) ABSTRACT

Implementations described herein disclose a laser diode driver that allows switching low-voltage (LV) high-speed devices with while driving high voltage current to a laser diode without risking destroying the LV devices. Specifically, the laser diode driver disclosed herein is a pulsed high speed digital to analog (DAC) driver that uses high-speed LV transistors in advanced nodes for high-speed switching of current nodes.

### CROSS-REFERENCE TO RELATED APPLICATIONS

The present application claims benefit of priority to U.S. Provisional Patent Application No. 62/523,082, entitled “Laser Diode Driver” and filed on Jun. 21, 2017, which is specifically incorporated by reference for all that it discloses and teaches.

### BACKGROUND

Modern display systems include a large number of light sources such as laser diodes or light emitting diodes (LEDs) that need to be turned on and off at very high speed with high accuracy. Laser diode arrays and LED arrays are inductive loads and they generate high transient currents. When such inductive loads are driven at high voltage levels, the resulting current transients does not allow use of high frequency low voltage switching system. Furthermore, the high current transients may also damage low voltage reference current generation modules.

### SUMMARY

Implementations described herein disclose an apparatus that allows a display system that require high voltage and are adversely affected by high inductive load to be switched using low voltage switching circuit. An implementation of the apparatus includes a digital to analog converter (DAC) module consisting out of a low-voltage high speed switching system and a high voltage driving system for inductive loads, a switching module for switching the DAC module, a reference current generation module for generating reference current for the DAC module, and a bias section configured between the DAC module and the reference current generation module to protect the reference current generation module from transient spikes generated by the inductive load.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Other implementations are also described and recited herein.

### BRIEF DESCRIPTIONS OF THE DRAWINGS

A further understanding of the nature and advantages of the present technology may be realized by reference to the figures, which are described in the remaining portion of the specification. In the figures, like reference numerals are used throughout several figures to refer to similar components.

FIG. 1 illustrates an example implementation of the display system driver disclosed herein.

FIG. 2 illustrates an alternative example implementation of the display system driver disclosed herein.

FIG. 3 illustrates an example schematics of the display system driver disclosed herein.

FIG. 4 illustrates an example implementation of a reference current generation module disclosed herein.

FIG. 5 illustrates an example implementation of a color digital to analog converter (DAC) disclosed herein.

### DETAILED DESCRIPTIONS

Aspects of this disclosure will now be described by example and with reference to the illustrated embodiments listed above.

Implementations described herein disclose a display system driver that allows using low-voltage (LV) high-speed switching devices while driving high voltage current to a display system using an array of laser diodes such that the LV switching devices are protected from transient currents generated by the inductive laser diodes. In one implementation, the laser diode driver disclosed herein is a pulsed high-speed digital to analog converter (DAC) driver that uses high-speed LV transistors in advanced nodes for high-speed switching of high-voltage current mirrors driving the laser diodes. Specifically, the implementations disclosed herein include high-speed LV transistors that enables high speeds and HV current mirrors that enables the ability to drive the high voltage laser diodes with high inductive loads.

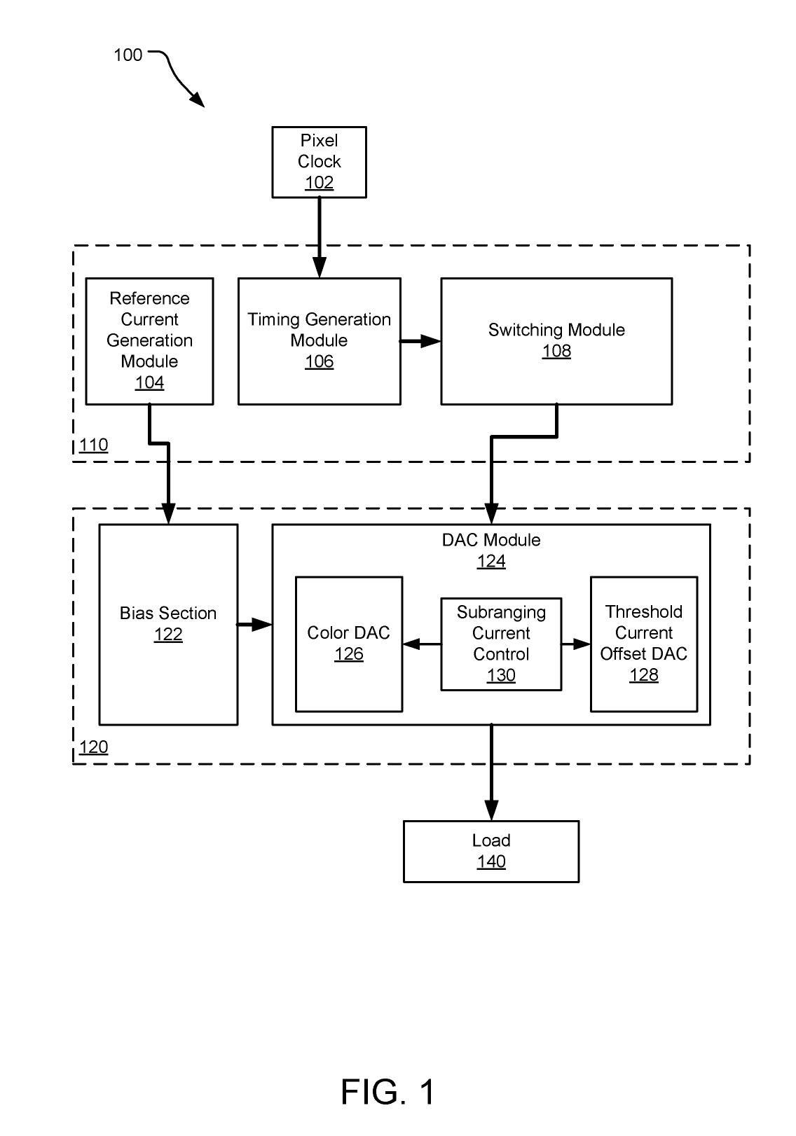

FIG. 1 illustrates an example implementation of the display system driver 100 disclosed herein. Specifically, the display system driver 100 may be used to drive a load 140. For example, the load 140 may be an inductive load, such as an array of laser diodes, an array of LEDs, etc. The display system driver 100 includes a low voltage section 110 including a number of modules that function at low voltage. In one implementation, the modules in the low voltage section 110 operate at about 1.1V level. The load 140 is driven by a high voltage section 120 with a number of modules that operate in the high voltage range. In one implementation, various modules of the high voltage section 120 operate at voltages higher than −3.0V.

The low voltage section 110 includes a reference current generation module 104. In one implementation, the reference current generation module 104 includes a 6-bit current reference DAC with dual channel output. The reference current generation module 104 may generate the reference signal of 48 μA to 192 μA at 1.1V. The current equation Iₘₐₓ=I_{device}*(0.5+(1.5*RefDACᵥₐₗ/64)) describes the resulting current for digital decimal programming code values from 0-64. The reference signal generated by the reference current generation module 104 is fed to a bias section 122.

A timing generation module 106 receives a pixel clock signal 102 and generates a number of timing signals. In one implementation, the timing generation module 106 may be implemented using a delay-locked loop (DLL) circuit that generates a series of outputs that are input to a switching module 108.

The switching module 108 may be implemented using a thermometer coded DAC, which contains an equal resistor or current-source segment for each possible value of DAC output. For example, the switching module 108 includes a 10-bit thermometer DAC that generates 1K segments as its output signal. Specifically, the 10 bit thermometer DAC creates a threshold and a background current value, however it does not switch fast in normal operation. The segmented output signal from the switching module 108 is used to switch a DAC module 124 that drives the load 140. Specifically, an 11-bit thermometer DAC generates color pixel values and is configured to switch at high speed.

The low voltage section 120 includes a bias section 122 that converts the reference bias from the reference current generation module 104 from low voltage domain into a high voltage domain signal. Specifically, the bias section 122 includes a number of common gate cascode amplifiers that protects the reference current generation module 104 from transient spike from the load 140. In one implementation, the common gate cascode amplifiers used in the bias section 122 are p-channel common gate cascode amplifiers.

The common gate cascode amplifiers used in the bias section 122 generates an output signal that mirrors the bias signal input into the bias section 122 from the reference current generation module 104. This mirrored output signal is input into the DAC module 124. Furthermore, the bias section 122 also increases the voltage level of the signal input from the reference current generation module 104. For example, the voltage level of the signal input to the bias section 122 may be 1.1V whereas the voltage level of the signal output from the bias section 122 may be higher than −3V. In one implementation, the voltage level of the signal output from the bias section 122 may be in the range of −3V to −8V.

The p-channel cascode amplifiers used in the bias section 122 also prevents the current over swing or spike generated in the DAC module 124 due to driving the load 140 from reaching the reference current generation module 104. Specifically, transistors at the top of the p-channel cascode amplifiers that are connected to receive input from the reference current generation module 104 are biased such that the voltage level at their sources does not go below ground level. As a result, the voltage level seen at the output terminals of the reference current generation module 104 is protected between ground and 1.1V.

The DAC module 124 includes a color DAC 126, a threshold current offset DAC 128, and a sub-ranging current control module 130. The threshold current offset DAC 128 is a 10-bit binary coded DAC whereas the color DAC 126 is an 11 bit DAC. The sub-ranging current control module 130 provides 5-bit global brightness sub-ranging current control to the color DAC 126 and the threshold current offset DAC 128.

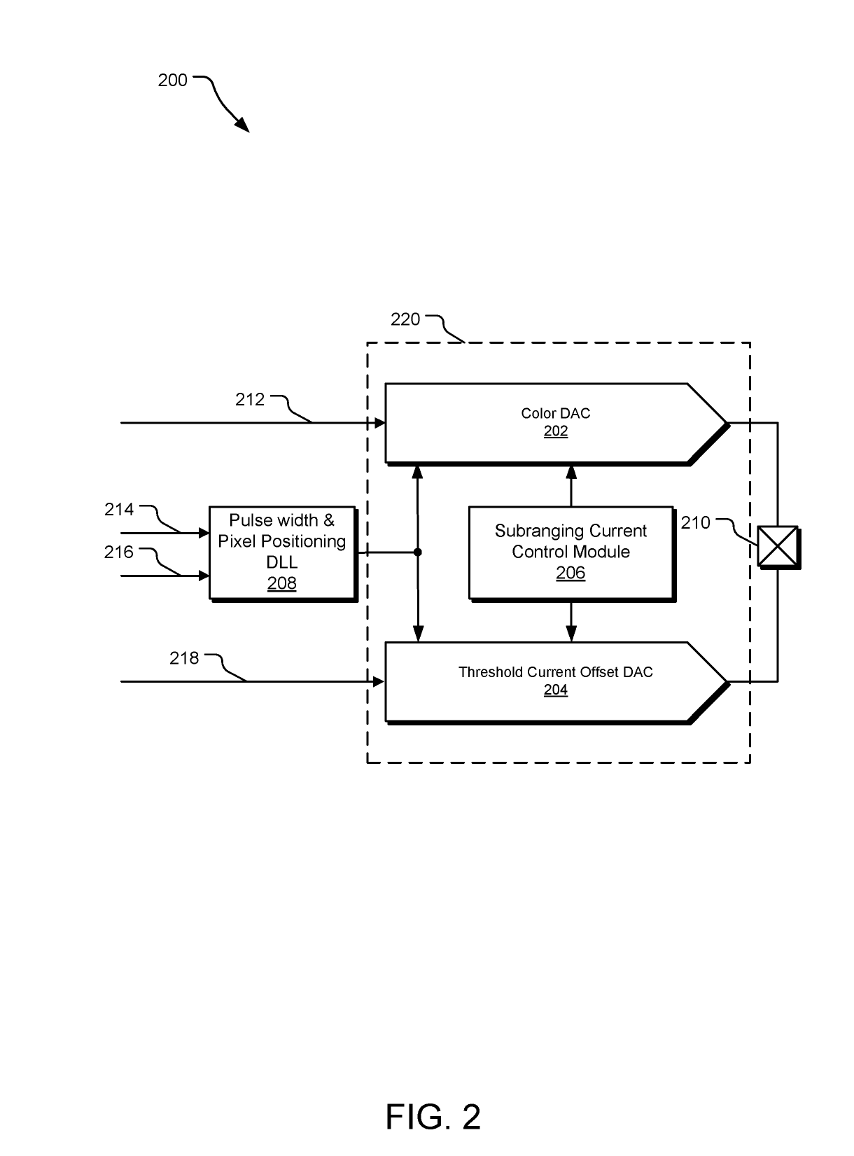

FIG. 2 illustrates an alternative example implementation of the display system driver 200 disclosed herein. Specifically, the display system driver 200 includes a high voltage section 220 with various components that drive a load 210. In the illustrated implementation, the high voltage section 220 includes a color DAC 202, a threshold current offset DAC 204, and a sub-ranging current control module 206.

The color DAC 202 and the threshold current offset DAC 204 are switched by signal from a pulse width and pixel positioning DLL 208. In one implementation, the pulse width and pixel positioning DLL 208 is a DLL with 64 taps. Specifically, the pulse width and pixel positioning DLL 208 may be implemented in a low voltage domain. The pulse width and pixel positioning DLL 208 receives a pixel offset signal 214 and a pixel clock signal 216.

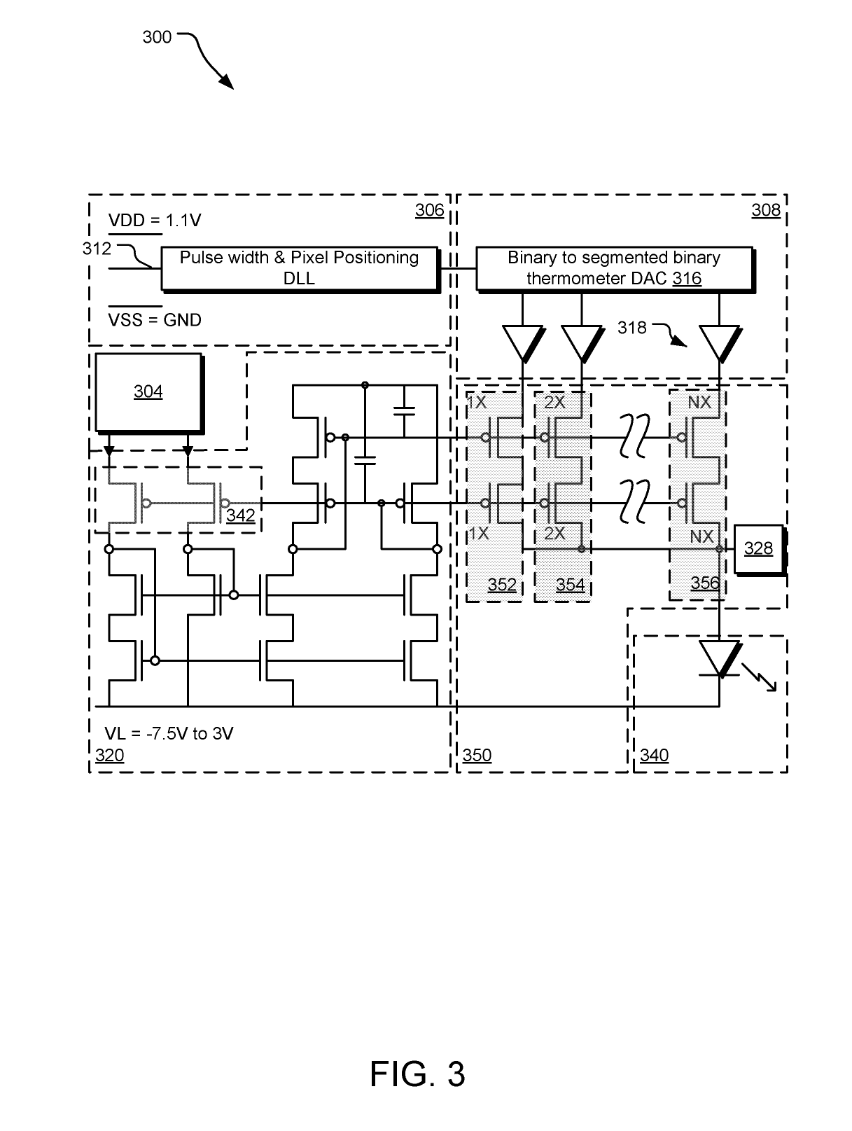

FIG. 3 illustrates an example schematics of the display system driver 300 disclosed herein. Specifically, the display system driver 300 is illustrated to show details of a 10-bit threshold current offset DAC 350 with sub-ranging current control modules 352, 354, 356. The display system driver 300 may be used to drive an inductive load 340, such as an array of laser diodes, an array of LEDs, etc.

The display system driver 300 includes a low voltage section including a number of modules that function at low voltage. In one implementation, the modules in the low voltage section operate at about 1.1V level. The load 340 is driven by a high voltage section with a number of modules that operate in the high voltage range. In one implementation, various modules of the high voltage section operate at voltages higher than −3.0V. The low voltage section of the display system driver 300 includes a reference current generation module 304, a timing generation module 306, and a switching module 308. The switching module 308 may include a binary to segmented binary thermometer DAC 316 that feeds its output to a number of low voltage buffers 318. In one implementation, the transistors used in the binary to segmented binary thermometer DAC 316 and the low voltage buffers 318 are low voltage transistors. The timing generation module 306 may be implemented using a pulse width and pixel positioning DLL module. The pulse width and pixel positioning DLL module may receive a pixel clock signal 312 and generates a series of outputs that are input to the switching module 308.

The reference current generation module 304 may include a 6-bit current reference DAC with dual channel output. The reference signal generated by the reference current generation module 304 is fed to a bias section 320. The bias section converts the reference bias from the reference current generation module 304 from low voltage domain into a high voltage domain signal. Specifically, the bias section 320 includes a number of common gate cascode amplifiers that protects the reference current generation module 304 from transient spike from the load 340. In one implementation, the common gate cascode amplifiers used in the bias section 320 are p-channel common gate cascode amplifiers.

The common gate cascode amplifiers used in the bias section 320 generates an output signal that mirrors the bias signal input into the bias section 320 from the reference current generation module 304. This mirrored output signal is input into the DAC module 350. Furthermore, the bias section 320 also increases the voltage level of the signal input from the reference current generation module 304. For example, the voltage level of the signal input to the bias section 320 may be 1.1V whereas the voltage level of the signal output from the bias section 320 may be higher than −3V. In one implementation, the voltage level of the signal output from the bias section 320 may be in the range of −3V to −7.5V.

The p-channel cascode amplifiers used in the bias section 320 also prevents the current over swing or spike generated in the DAC module 350 due to driving the load 340 from reaching the reference current generation module 304. Specifically, transistors 342 at the top of the p-channel cascode amplifiers that are connected to receive input from the reference current generation module 304 are biased such that the voltage level at their sources does not go below ground level. As a result, the voltage level seen at the output terminals of the reference current generation module 304 is protected between ground and 1.1V. The DAC module 350 is illustrated to include an 11-bit color DAC 328 and the sub-ranging current control modules 352, 354, 356. In one implementation, the DAC 328 may be a thermometer coded 11 bit DAC with 2047 current sources, thus requiring 2047 sub-ranging sections in the DAC module 350. A sub-ranging control module may be used to control the sub-ranging settings of the DAC module 350.

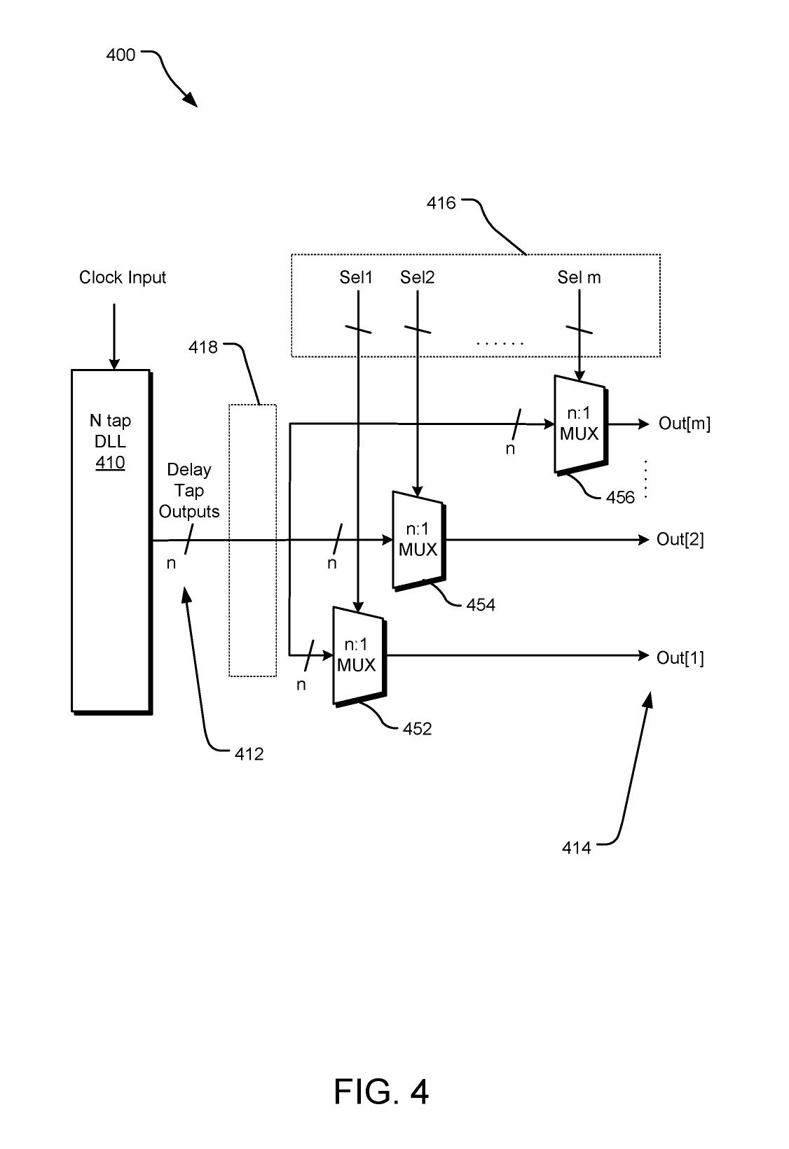

FIG. 4 illustrates an example implementation of a reference current generation module 400 disclosed herein. Specifically, FIG. 4 illustrates a scalable clocking system 400 used with multiple delay taps assigned to multiple outputs to generates timing signals. Specifically, the reference current generation module 400 is implemented using an n-tap DLL circuit 410 that generates clock output signals at n delay taps 412. The reference current generation module 400 allows for each of the n delay taps 412 to be assigned to any of M outputs 414. Therefore, the reference current generation module 400 can be used to generate multiple clock outputs that have a controlled phase relationship to each other.

An implementation of the reference current generation module 400 ensures that the phase of the outputs 414 changes in a monotonic phase with each increment in the phase selection input code across all outputs 414. Specifically, output on the delay taps 412 is buffered using selectable buffers 418 such that output on all taps is available for potential use across all 2:1 multiplexers 452-456 as determined by a selection logic 416. Furthermore, any delay through the selectable buffers 418 is to be minimized in order that its variation is small compared to the incremental delay in the delay line of the DLL 410 to ensure that the selected incremental output 414 is monotonic with the delay selection input code as per the selection logic 416.

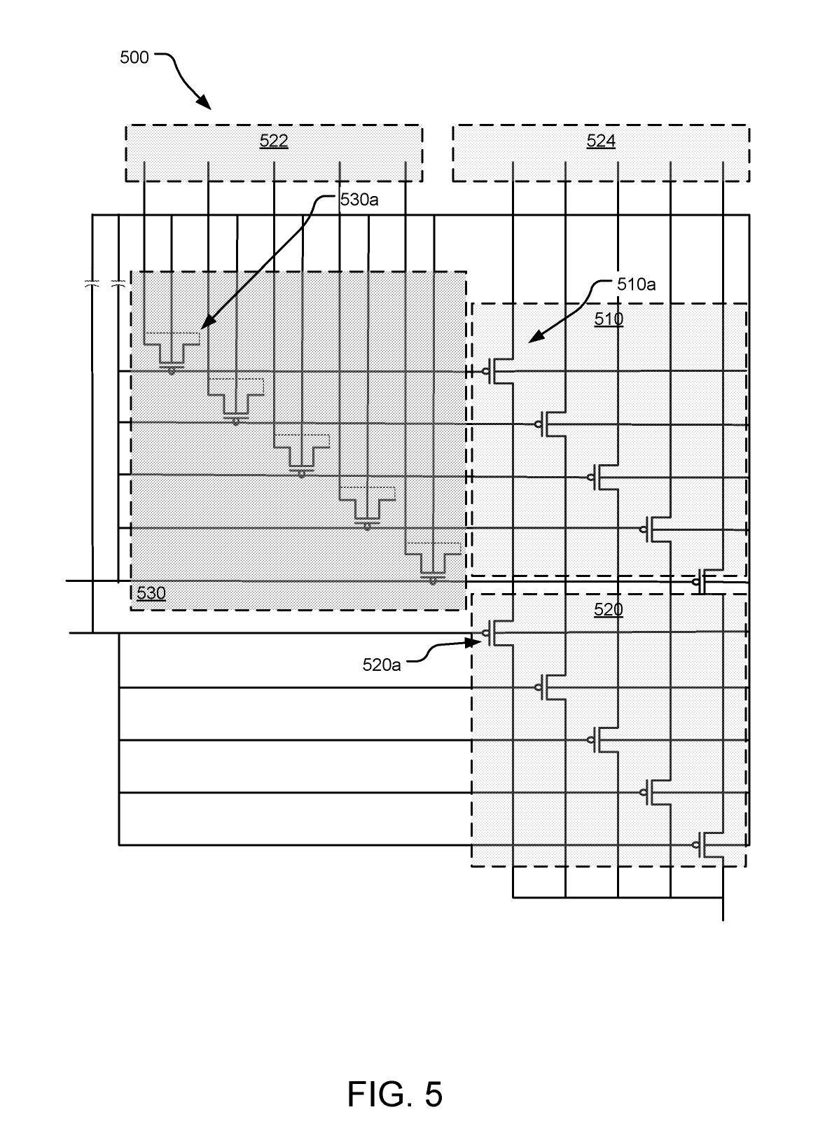

FIG. 5 illustrates an example implementation of a color DAC 500 disclosed herein. Specifically, the color DAC 500 is illustrated to function in high voltage domain. The color DAC 500 is an eleven bit DAC with additional 5-bit sub-ranging provided by sub-ranging transistors 510 and 520. The color DAC 500 receives switching inputs 522 and 524 from a low voltage switching module. The illustrated implementation of the color DAC 500 also includes a charge injection cancellation module 530 that cancels charge injection at the gates of the transistors in the sub-ranging modules 510 and 520. For example, the transistor 530a provides cancellation of charge across the gate and source of the transistors 510a and 510b.

An implementation of the color DAC 500 provides 11-bit per pixel current amplitude control and 5-bit global brightness control. The color DAC 500 may provide up to 256 mA current for red laser diodes and up to 128 mA current for green and blue laser diodes.

The display system driver disclosed herein utilizes the high-speed low voltage transistors in advanced nodes for high-speed switching of the current sources. A high-performance common gate amplifier cascode system allows for the full protection of the low voltage transistor switching system from any high voltage switching transients occurring while switching an inductive laser diode. Furthermore, implementations of the display system driver disclosed herein provides following performance parameters:

Per pixel pulsed amplitude control with 10-bit control

Global brightness control, which is a low voltage current DAC that allows for multiplying the 6-bit accurate current into the 10-bit laser pixel DAC

6-bit of global brightness current adjustment

2-bit of pulse width adjustment around the center position

6-bit of pulse position control for centering the pulse in the pixel

Pulsed threshold current offset DAC with 10-bit control

The display system driver disclosed herein allows switching laser diodes or other loads with much smaller rise and fall time compared to other laser drivers. For example, while other laser diode drivers can only switch the laser with rise and fall times above 1-2 ns and pulse periods of 10 ns, the display system driver disclosed herein allows switching high voltage loads with rise and fall time in the range of 205-300 picoseconds. Furthermore, other laser diode driver systems used to go this high-speed are Non_Return to Zero systems. Such Non_Return to Zero systems result in consuming large amounts of power. Compared to that, the display system driver disclosed herein provides high speed switching without the system being a Non_Return to Zero system. While other systems are not capable of switching at the high speeds due to high inductance and slow speed induced by the high voltage transistors, the system disclosed herein mirrors the current in the HV domain but switches the current in the LV domain, therefore allowing the system to return to zero between each pixel value.

In some implementation, the display system driver disclosed herein may be driven with 1-2 ns total pulse width and pulse periods around 4 ns while being able to settle to at least 6-bit accuracy within this pulse width and returning to zero after each and every pulse. Furthermore, the display system driver disclosed herein can reduce the power needed compared to other systems by an order of magnitude while providing for more accurate and higher speed operation.

An implementation of the apparatus disclosed herein includes a digital to analog converter (DAC) module for driving a system with an inductive load, a switching module for switching the DAC module, a reference current generation module for generating reference current for the DAC module, and a bias section configured between the DAC module and the reference current generation module to protect the reference current generation module from transient spikes generated by the inductive load. In one implementation, the bias section includes a common gate cascode amplifier. In another implementation, the common gate cascode amplifier is a p-channel common gate cascode amplifier. In yet another implementation, the DAC module includes a color DAC and a threshold current offset DAC. In another implementation, the color DAC module provides 11-bit per pixel current amplitude control.

In one implementation of the apparatus, the color DAC module provides 5-bit global brightness control. In another implementation, the inductive load is an array of laser diodes. In another implementation, the switching module operates in low voltage domain between ground and approximately 1.1V. In yet another implementation, the reference current generation module operates in low voltage domain between ground and approximately 1.1V and the DAC module operates in a high voltage domain between approximately −3V and −8V. In another implementation, the switching module receives accurate timing signals from a DLL functioning in a low voltage domain.

A display system driver disclosed herein includes a digital to analog converter (DAC) module for driving a system with an inductive load, a reference current generation module for generating reference current for the DAC module, and a bias section configured between the DAC module and the reference current generation module to protect the reference current generation module from transient spikes generated by the inductive load. An implementation of the display system driver further includes a switching module for switching the DAC module. In one implementation, the switching module function in a low voltage domain between ground and approximately 1.1V and the DAC module operates in a high voltage domain between approximately −3V and −8V. In another implementation, the bias section includes a common gate cascode amplifier. In yet another implementation, the common gate cascode amplifier is a p-channel common gate cascode amplifier. In another implementation, wherein the inductive load is at least one of an array of laser diodes and an array of LEDs. In another implementation, the DAC module comprises a color DAC that provides 5-bit global brightness control and 11-bit per pixel current amplitude control.

A laser diode array driver disclosed herein includes a digital to analog converter (DAC) module for driving a laser diode array, wherein the DAC module operates in high voltage domain, a switching module for switching the DAC module, wherein the reference module operates in a low voltage domain, and a reference current generation module for generating reference current for the DAC module, wherein the current generation module operates in the low voltage domain and is separated from the DAC module by a bias section configured between the DAC module and the reference current generation module to protect the reference current generation module from transient spikes generated by the inductive load. In one implementation, the bias section comprises a common gate cascode amplifier. In another implementation, the common gate cascode amplifier is a p-channel common gate cascode amplifier.

The above specification, examples, and data provide a description of the structure and use of exemplary embodiments of the disclosed subject matter. Since many implementations can be made without departing from the spirit and scope of the disclosed subject matter, the claims hereinafter appended establish the scope of the subject matter covered by this document. Furthermore, structural features of the different embodiments may be combined in yet another implementation without departing from the recited claims.

What is claimed is:

1. An apparatus, comprising:
a digital to analog converter (DAC) module for driving a system with an inductive load;
a switching module for switching the DAC module;
a reference current generation module for generating reference current for the DAC module; and
a bias section configured between the DAC module and the reference current generation module to protect the reference current generation module from transient spikes generated by the inductive load.

2. The apparatus of claim 1, wherein the bias section includes a common gate cascode amplifier.

3. The apparatus of claim 2, wherein the common gate cascode amplifier is a p-channel common gate cascode amplifier.

4. The apparatus of claim 1, wherein the DAC module includes a color DAC and a threshold current offset DAC.

5. The apparatus of claim 4, wherein the color DAC module provides 11-bit per pixel current amplitude control.

6. The apparatus of claim 4, wherein the color DAC module provides 5-bit global brightness control.

7. The apparatus of claim 1, wherein the inductive load is an array of laser diodes.

8. The apparatus of claim 1, wherein the switching module operates in low voltage domain between ground and approximately 1.1V.

9. The apparatus of claim 1, wherein the reference current generation module operates in low voltage domain between ground and approximately 1.1V and the DAC module operates in a high voltage domain between approximately −3V and −8V.

10. The apparatus of claim 1, wherein the switching module receives accurate timing signals from a DLL functioning in a low voltage domain.

11. A display system driver, comprising:
a digital to analog converter (DAC) module for driving a system with an inductive load;
a reference current generation module for generating reference current for the DAC module; and
a bias section configured between the DAC module and the reference current generation module to protect the reference current generation module from transient spikes generated by the inductive load.

12. The display system driver of claim 11, further comprising a switching module for switching the DAC module.

13. The display system driver of claim 12, wherein the switching module function in a low voltage domain between ground and approximately 1.1V and the DAC module operates in a high voltage domain between approximately −3V and −8V.

14. The display system driver of claim 11, wherein the bias section includes a common gate cascode amplifier.

15. The display system driver of claim 14, wherein the common gate cascode amplifier is a p-channel common gate cascode amplifier.

16. The display system driver of claim 11, wherein the inductive load is at least one of an array of laser diodes and an array of LEDs.

17. The display system driver of claim 11, wherein the DAC module comprises a color DAC that provides 5-bit global brightness control and 11-bit per pixel current amplitude control.

18. A laser diode array driver, comprising:
a digital to analog converter (DAC) module for driving a laser diode array, wherein the DAC module operates in high voltage domain;
a switching module for switching the DAC module, wherein the reference module operates in a low voltage domain; and
a reference current generation module for generating reference current for the DAC module, wherein the current generation module operates in the low voltage domain and is separated from the DAC module by a bias section configured between the DAC module and the reference current generation module to protect the reference current generation module from transient spikes generated by the inductive load.

19. The laser diode array driver of claim 18, wherein the bias section comprises a common gate cascode amplifier.

20. The laser diode array driver of claim 19, wherein the common gate cascode amplifier is a p-channel common gate cascode amplifier.
